(19) United States
(12) Patent Application Publication
(10) Pub. No.: US 2021/0319312 A1
(43) Pub. Date: Oct. 14, 2021

(54) DEEP LEARNING ACCELERATION OF PHYSICS-BASED MODELING

(71) Applicant: ADVANCED MICRO DEVICES, INC., Santa Clara, CA (US)

(72) Inventors: Nicholas Penha MALAYA, Austin, TX (US); Abhinav VISHNU, Austin, TX (US); Octavi OBIOLS SALES, Austin, TX (US)

(21) Appl. No.: 17/007,489

(22) Filed: Aug. 31, 2020

Related U.S. Application Data
(60) Provisional application No. 63/009,282, filed on Apr. 13, 2020.

(51) Int. Cl. G06N 3/08; G06F 17/17

(52) U.S. Cl. CPC G06N 3/08; G06F 17/17

(57) ABSTRACT

Values of physical variables that represent a first state of a first physical system are estimated using a deep learning (DL) algorithm that is trained based on values of physical variables that represent states of other physical systems that are determined by one or more physical equations and subject to one or more conservation laws. A physics-based model modifies the estimated values based on the one or more physical equations so that the resulting modified values satisfy the one or more conservation laws.

### CROSS-REFERENCE TO RELATED APPLICATIONS

The present application claims priority to Provisional Patent Application Ser. No. 63/009,282, entitled “CFDNET: A Deep Learning-Based Accelerator for Fluid Simulations” and filed on Apr. 13, 2020, the entirety of which is incorporated by reference herein.

### BACKGROUND

Physics-based modeling represents real world processes or physical systems using numerical solutions of physics equations that describe physical processes in the real world. Examples of the physics equations that are used in physics-based models include Newton's equations of motion, Maxwell's equations of electrodynamics, Einstein's relativistic equations of motion, Schrödinger's equations for quantum mechanics, Navier-Stokes equations of fluid dynamics, and the like. These equations, or combinations thereof, are typically represented as partial differential equations that are solved iteratively to determine values of variables that represent the physical state of cells in a discretized geometry such as a grid or a mesh. Solutions to the physics equations used in physics-based modeling are typically constrained to satisfy physical conservation laws such as conservation of mass, conservation of energy, conservation of momentum, conservation of charge, and the like, e.g., by including a corresponding continuity equation in the physics-based model. The solutions include static solutions that converge to time-independent values of the variables in the cells or dynamic solutions that produce time-dependent values of the variables in the cells. For example, computational fluid dynamics (CFD) is used to solve the Navier-Stokes equations in static geometries such as fluid flow past a fixed object and dynamic geometries such as weather systems. However, physics-based modeling of equations such as the Navier-Stokes equations is computationally expensive and typically subject to a trade-off between accuracy and computational costs.

### BRIEF DESCRIPTION OF THE DRAWINGS

The present disclosure may be better understood, and its numerous features and advantages made apparent to those skilled in the art by referencing the accompanying drawings. The use of the same reference symbols in different drawings indicates similar or identical items.

FIG. 1 is a block diagram of a processing system that accelerates convergence of a physics-based solver using a deep learning (DL) algorithm according to some embodiments.

FIG. 2 shows an initial state and a final state of a computational fluid dynamics (CFD) simulation according to some embodiments.

FIG. 3 is a block diagram of an input that represents a set of physical variables that are mapped to corresponding channels for provision to the DL algorithm according to some embodiments.

FIG. 4 is a block diagram of a convolutional neural network (CNN) architecture that is used to implement a DL algorithm according to some embodiments.

FIG. 5 is a block diagram of a processing system that implements a DL algorithm to accelerate a physics-based solver according to some embodiments.

FIG. 6 is a flow diagram of a method of accelerating a physics-based solver using a DL algorithm according to some embodiments.

FIG. 7 is a flow diagram of a method of executing a physics-based solver to solve a set of equations that represent a state of a physical system according to some embodiments.

### DETAILED DESCRIPTION

Machine learning methods, including deep learning (DL), are widely used to perform modeling/classification tasks such as computer vision, natural language processing, and high-performance computing. Conventional DL algorithms are implemented using neural networks such as deep neural networks (DNNs), convolutional neural networks (CNNs), recurrent neural networks (RNN), and the like. A CNN architecture includes a stack of layers that implement functions to transform an input volume (such as a digital image) into an output volume (such as labeled features detected in the digital image). A DNN performs deep learning on tasks that contain multiple hidden layers. For example, a DNN that is used to implement computer vision includes explicit functions (such as orientation maps) and multiple hidden functions in the hierarchy of vision flow. The layers in a CNN are separated as an example into convolutional layers, pooling layers, and fully connected layers. In some embodiments, multiple sets of convolutional, pooling, and fully connected layers are interleaved to form a complete CNN. The functions implemented by the layers in a CNN are explicit (i.e., known or predetermined) or hidden (i.e., unknown). An RNN is a type of artificial neural network that forms a directed graph of connections between nodes along a temporal sequence and exhibits temporal dynamic behavior.

Attempts have been made to accelerate physics-based models by incorporating DL algorithms. For example, DL algorithms have been applied to accelerate computational fluid dynamics (CFD) simulations. However, DL algorithms are not constrained by the physical requirements of the relevant equations or conservation laws, such as the Navier-Stokes equations that govern fluid flows. Instead, DL algorithms are trained to recognize patterns of physical variables using data from previous physics-based models in related contexts. Neglecting the physical requirements of the situation leads to several drawbacks. For example, techniques based on DL algorithms typically do not satisfy the relevant conservation laws. Second, a conventional DL algorithm typically predicts a partial flow field that includes a subset of the flow variables that provide incomplete information about the physical context. For example, DL algorithms are not applied to turbulent flows that are common in most industrial applications. Furthermore, the DL algorithms are trained based on training input such as a training geometry that is the same as (or similar to a test geometry that the DL algorithm is attempting to model. Thus, the DL algorithms are not easily generalized to other geometries.

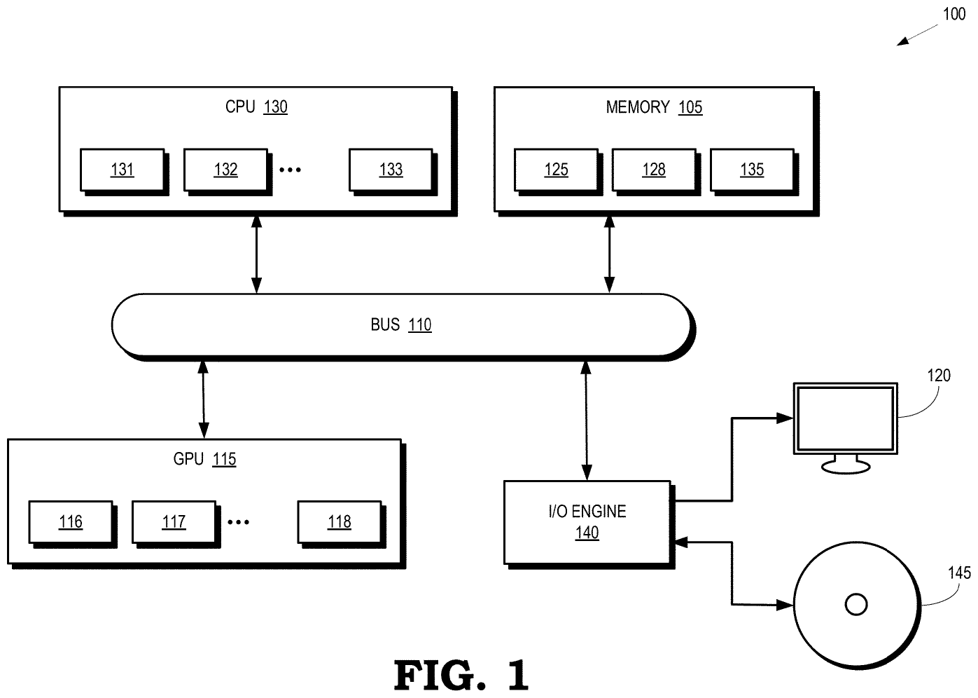

FIGS. 1-7 disclose systems and techniques for combining the relative speed of deep learning (DL) algorithms and the accuracy of physics-based modeling by estimating values of physical variables using a DL algorithm that is trained on data generated using a physics-based model. The estimated values of the physical variables are provided as input to the physics-based model, which is then executed to modify the estimated values generated by the DL algorithm and produce final values of the physical variables. In some embodiments, the physics-based model applies at least one conservation law that is satisfied by the final values of the physical variables generated by the physics-based model to a predetermined accuracy or convergence criterion represented by one or more thresholds. Some embodiments of the physics-based model use CFD to solve the Navier-Stokes equations in a physical context. The estimated values generated by the DL algorithm and the modified values generated by the physics-based model represent static, time-independent values of the physical variables that represent a time-independent state of the physical system or dynamic, time-dependent values of the physical variables that represent a time-dependent state of the physical system. Some embodiments of the DL algorithm include a DNN that implements domain-specific activation functions to predict values of the physical variables in a grid of cells that represents a physical context. Initial values of the physical variables are provided to the DNN as a set of channels. In some embodiments, the initial values for the DNN are generated by one or more iterations of the physics-based model during a preconditioning phase. Training of some embodiments of the DNN is updated using intermediate iterations as an input and an output of the DNN as a target variable.

FIG. 1 is a block diagram of a processing system 100 that accelerates convergence of a physics-based solver using a DL algorithm according to some embodiments. The processing system 100 includes or has access to a memory 105 or other storage component that is implemented using a non-transitory computer readable medium such as a dynamic random access memory (DRAM), static random access memory (SRAM), nonvolatile RAM, and the like. The processing system 100 also includes a bus 110 to support communication between entities implemented in the processing system 100, such as the memory 105. Some embodiments of the processing system 100 include other buses, bridges, switches, routers, and the like, which are not shown in FIG. 1 in the interest of clarity.

The processing system 100 includes at least one graphics processing unit (GPU) 115 that renders images for presentation on a display 120. For example, the GPU 115 renders objects to produce values of pixels that are provided to the display 120, which uses the pixel values to display an image that represents the rendered objects. Some embodiments of the GPU 115 are used to implement DL operations including CNNs, DNNs, and RNNs, as well as performing other general-purpose computing tasks. In the illustrated embodiment, the GPU 115 implements multiple processing elements 116, 117, 118 (collectively referred to herein as “the processing elements 116-118”) that execute instructions concurrently or in parallel. In the illustrated embodiment, the GPU 115 communicates with the memory 105 over the bus 110. However, some embodiments of the GPU 115 communicate with the memory 105 over a direct connection or via other buses, bridges, switches, routers, and the like. The GPU 115 executes instructions stored in the memory 105 and the GPU 115 stores information in the memory 105 such as the results of the executed instructions. In the illustrated embodiment, the memory 105 stores a copy of instructions from program code that represents a physics-based solver 125 and a copy of instructions from program code that represents a DL algorithm 128.

The processing system 100 also includes at least one central processing unit (CPU) 130 that implements multiple processing elements 131, 132, 133, which are collectively referred to herein as “the processing elements 131-133.” The processing elements 131-133 execute instructions concurrently or in parallel. The CPU 130 is connected to the bus 110 and therefore communicates with the GPU 115 and the memory 105 via the bus 110. The CPU 130 executes instructions such as program code 135 stored in the memory 105 and the CPU 130 stores information in the memory 105 such as the results of the executed instructions. The CPU 130 is also able to initiate graphics processing by issuing draw calls to the GPU 115. Some embodiments of the CPU 130 execute portions of the copy of the program code for a physics-based solver 125, portions of the copy of the program code for the DL algorithm 128, or a combination thereof.

An input/output (I/O) engine 140 handles input or output operations associated with the display 120, as well as other elements of the processing system 100 such as keyboards, mice, printers, external disks, and the like. The I/O engine 140 is coupled to the bus 110 so that the I/O engine 140 communicates with the memory 105, the GPU 115, or the CPU 130. In the illustrated embodiment, the I/O engine 140 reads information stored on an external storage component 145, which is implemented using a non-transitory computer readable medium such as a compact disk (CD), a digital video disc (DVD), and the like. The I/O engine 140 also writes information to the external storage component 145, such as the results of processing by the GPU 115 or the CPU 130.

The physics-based solver 125 is used to solve a set of one or more physical equations and, in some embodiments, corresponding conservation laws (e.g., conservation laws that are represented by one or more continuity equations) that determine the values of physical variables that represent a state of a physical system. To illustrate, some embodiments of the physics-based solver 125 are configured to solve the Navier-Stokes equations:

$$\frac{\partial {\overline{U}}_{ι}}{\partial {x}_{i}} = 0$$

$${\overline{U}}_{j} \frac{\partial {\overline{U}}_{ι}}{\partial {x}_{j}} = \frac{\partial }{\partial {x}_{j}} [ - ( \overline{p} ) {δ}_{i j} + ( v + {v}_{t} ) ( \frac{\partial {\overline{U}}_{ι}}{\partial {x}_{j}} + \frac{\partial {\overline{U}}_{j}}{\partial {x}_{i}} ) ]$$

The variables in the Navier-Stokes equations are the mean velocity (Ū), the kinematic mean pressure (p̅), the fluid viscosity (v), and the eddy viscosity (v̅). The Navier-Stokes equations are supplemented by the Spalart-Allmaras one-equation model for the eddy viscosity (\tilde{v}):

$${\overline{U}}_{ι} \frac{\partial \tilde{v}}{\partial {x}_{i}} = {C}_{b 1} ( 1 - {f}_{t 2} ) \tilde{S} \tilde{v} - [ {C}_{w 1} {f}_{w} - \frac{{C}_{b 1}}{{κ}^{2}} {f}_{t 2} ] ( \frac{{\tilde{v}}^{2}}{d} ) + \\ \frac{1}{σ} [ \frac{\partial }{\partial {x}_{i}} ( ( v + \tilde{v} ) \frac{\partial \tilde{υ}}{\partial {x}_{i}} ) + {C}_{b 2} \frac{\partial \tilde{υ}}{\partial {x}_{j}} \frac{\partial \tilde{υ}}{\partial {x}_{j}} ]$$

These equations form a system of four partial differential equations in two-dimensions (2D) and five partial differential equations in three dimensions (3D). The physics-based solver 125 solves discretized forms of these equations on a structured grid with corresponding boundary conditions using numerical finite difference techniques.

The DL algorithm 128 is implemented using one or more artificial neural networks, such as a CNN, DNN, or RNN, which are represented as program code that is configured using a corresponding set of parameters. The artificial neural network is therefore executed on one or more GPUs 115, one or more CPUs 130, or other processing units including field programmable gate arrays (FPGA), application-specific integrated circuits (ASIC), and the like, or combinations of such processing units. If the artificial neural network implements a known function that is trained using a corresponding known dataset, the artificial neural network is trained (i.e., the values of the parameters that define the artificial neural network are established) by providing input values of the known training data set (e.g., the training input) to the artificial neural network executing on the GPU 115 or the CPU 130 and then comparing the output values of the artificial neural network to labeled output values in the known training data set. Error values are determined based on the comparison and back propagated to modify the values of the parameters that define the artificial neural network. This process is iterated until the values of the parameters satisfy a convergence criterion, e.g., as represented by one or more thresholds that are compared to values of the parameters. Some embodiments of the DL algorithm 128 are implemented using other input representations such as a 1-D representation.

Some embodiments of the DL algorithm 128 are trained using results of previous simulations performed by the physics-based solver 125. For example, CFD simulations can be performed for a set of training flow configurations. Images of the physical variables that represent the flow field at intermediate iterations (e.g., prior to convergence of the physics-based solver 125) are stored and used as inputs to the DL algorithm 128 during training. An image of the physical variables that represent the flow field after convergence of the physics-based solver 125 are stored and labeled as the target output for the DL algorithm 128 during training. However, in some embodiments, an intermediate output is stored prior to convergence of the physics-based solver 125 and labeled as the target output for the DL algorithm 128 during training. The DL algorithm 128 is then trained to produce the image of the converged values of the physical variables (or the intermediate output) in response to input representing the flow field at any of the intermediate iterations.

In operation, the GPU 115, the CPU 130, or a combination thereof execute the DL algorithm 128 on input values of the physical variables that represent a state of a physical system that is governed by one or more physical equations and one or more corresponding conservation laws. Some embodiments of the input values are determined by executing the physics-based solver 125 for one or more initial (or warm-up) iterations although the physics-base solver 125 does not perform warm-up interations in other embodiments. The values of the physical variables determined by the physics-based solver 125 during the warm-up iterations are provided as input values to the DL algorithm 128. The DL algorithm 128 infers estimated values of the physical variables that represent a state of the physical system. The estimated values of the physical variables are then provided as input to the physics-based solver 125, which is executed to modify the estimated values based on the one or more physical equations and conservation laws. In some embodiments, the physics-based solver 125 performs iterations until one or more convergence criteria and the corresponding conservation laws are satisfied within a tolerance. For example, the convergence criterion can be determined in terms of a rate of change of the physical variables between iterations and the conservation law is considered satisfied if the relevant quantity (e.g., mass, energy, momentum) is conserved within a predetermined tolerance.

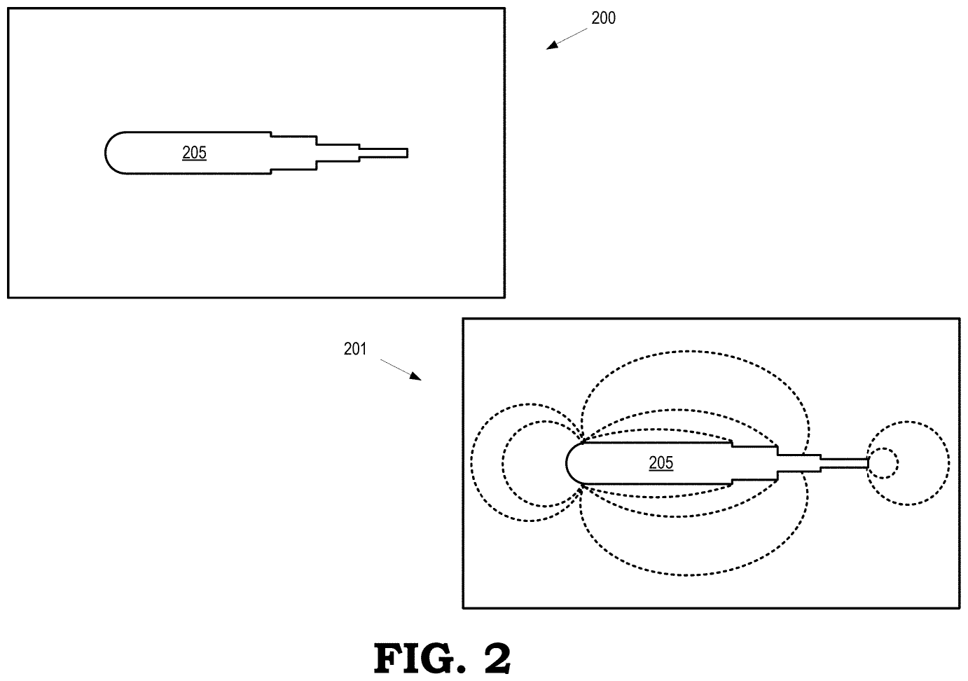

FIG. 2 shows an initial state 200 and a final state 201 of a CFD simulation according to some embodiments. The initial state 200 represents initial values of a flow variable such as velocity, pressure, or viscosity of the fluid in the presence of a cylindrical obstruction 205. The final state 201 of the CFD simulation represents the values of the flow variable in a steady-state determined by a physics-based solver using the Reynolds Averaged Navier-Stokes (RANS) simulation techniques and corresponding convergence constraints. As discussed herein, numerical models of the physical variables that represent a physical state of a physical system that is governed by a set of equations and corresponding conservation laws are time intensive and computationally intensive. For example, solving the Navier-Stokes equations using a physics-based solver requires committing a large amount of computing resources to the problem, making significant simplifications or approximations to the problem, or a combination thereof. Convergence of a physics-based solver is accelerated using the DL algorithm 128 to estimate values of the physical variables that are provided to the physics-based solver, which then refines the estimated values to produce a solution that satisfies the requirements of the set of equations and the corresponding conservation laws.

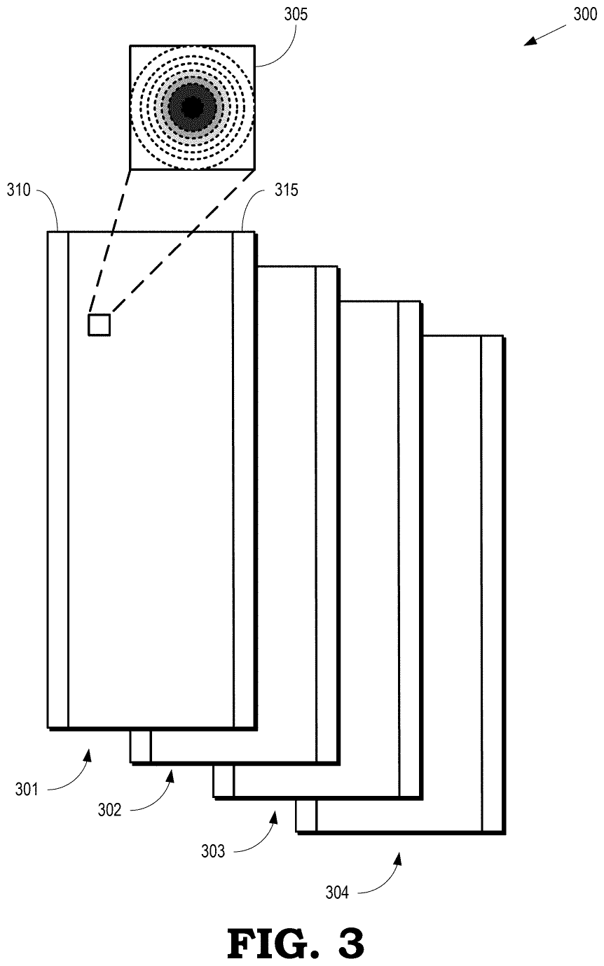

FIG. 3 is a block diagram of an input 300 that represents a set of physical variables that are mapped to corresponding channels for provision to the DL algorithm according to some embodiments. The input 300 includes images 301, 302, 303, 304 (collectively referred to herein as “the images 301-304”) that include pixels 305 (only one indicated by a reference numeral in the interest of clarity) having values of the corresponding physical variable. For example, the pixels in the image 301 can include values of a velocity of a fluid, pixels in the image 302 can include values of a pressure in the fluid, pixels in the image 303 can include values of the viscosity in the fluid, and the pixels in the image 304 can include values of the eddy viscosity in the fluid. The regions 310, 315 represent the boundary pixels that are subject to one or more boundary conditions on the corresponding variables.

In some embodiments, the values of the variables in the images 301-304 are non-dimensionalized. For example, the values of the variables in the pixels 305 are divided by a flow configuration-specific reference value corresponding to the variable. Non-dimensionalizing the variables in the images 301-304 addresses the (potentially large) differences in the scales or ranges of the values for the different variables. Non-dimensionalizing the variables in the images 301-304 also reduces the number of three parameters. If certain non-dimensionless parameters are significantly smaller than others, they are negligible in certain areas of the flow.

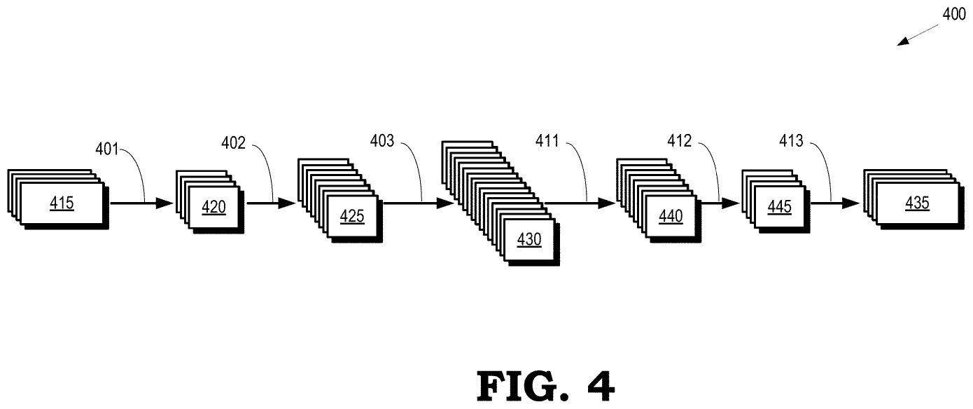

FIG. 4 is a block diagram of a CNN architecture 400 that is used to implement a DL algorithm according to some embodiments. The CNN architecture 400 is used to implement some embodiments of the DL algorithm 128 shown in FIG. 1. In the illustrated embodiment, the CNN architecture 400 is a symmetric 6-layer neural network that includes a set of convolution layers 401, 402, 403, which are collectively referred to herein as “the convolution layers 401-403.” The convolution layer 401 can be implemented using a parametric rectified linear unit (PreLU) activation function in the convolution layers 402, 403 can be implemented using a hyperbolic tangent (tan h) activation function. The CNN architecture 400 also includes a set of deconvolution layers 411, 412, 413, which are collectively referred to herein as “the deconvolution layers 411-413.” The deconvolution layers 411, 412 can be implemented using a tan h activation function and the deconvolution layer 413 can be implemented using a PreLU activation function.

The convolution layer 401 receives one or more input images 415 such as the input 300 shown in FIG. 3. The output 420 of the convolution layer 401 represents correlations within the flow variables in the input images 415. The output 420 is provided as input to the convolution layer 402. The output 425 of the convolution layer 402 represents correlations among the different flow variables in the input images 415. The output 425 is provided as input to the convolution layer 403 that further reduces the dimensionality by extracting an abstract representation of the input images 415 as the output 430.

An output image 435 of the same size as the input image 415 is reconstructed using the subsequent deconvolution layers 411-413. In the illustrated embodiment, the output 430 is provided to the deconvolution layer 411 that generates a corresponding output 440, which is provided to the deconvolution layer 412. Output 445 is generated by the deconvolution layer 412 and provided to the deconvolution layer 413, which uses the output 445 as an input to produce the output image 435. The PReLU activation functions implemented in the convolution layer 401 and the deconvolution layer 413 capture negative values present in the intermediate field represented by the input image 415 and predict final, real valued variables for the output image 435.

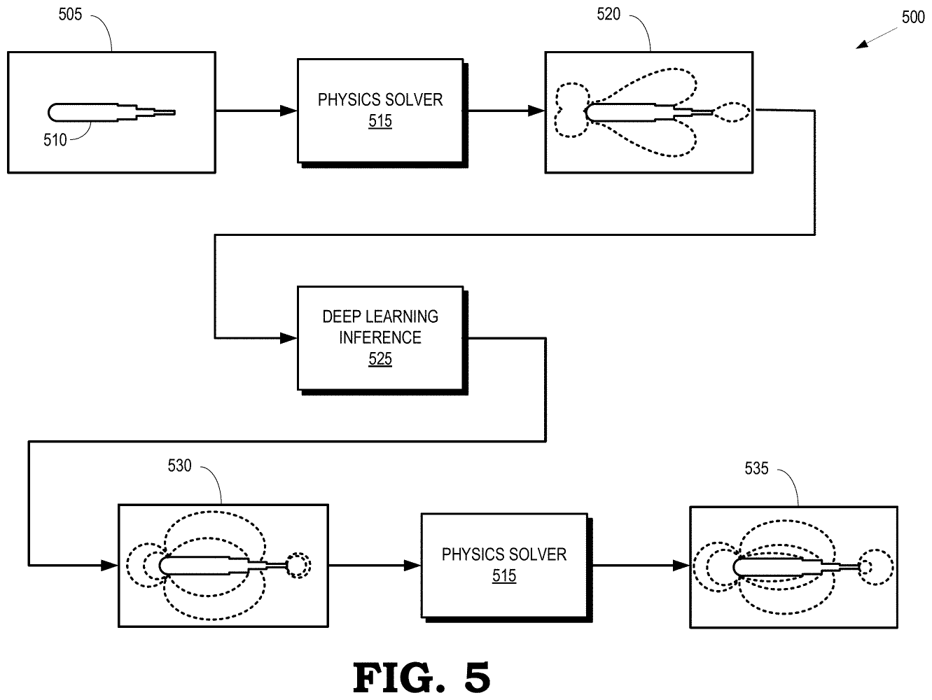

FIG. 5 is a block diagram of a processing system 500 that implements a DL algorithm to accelerate a physics-based solver according to some embodiments. The processing system 500 is instantiated in some embodiments of the processing system 100 shown in FIG. 1. The processing system 500 receives input 505 is an image or set of images of physical variables that represent a physical system. In the illustrated embodiment, the input 505 represents flow variables in a CFD simulation of a fluid flowing around an object 510. The processing system 500 therefore produces a steady-state solution for the physical variables, i.e., a time-independent final state of the physical variables. However, some embodiments of the processing system 500 perform simulations of dynamic, time-dependent systems such as the weather.

In some embodiments, the input 505 is provided to an instance of a physics-based solver 515 that performs one or more iterations of a numerical solution of the set of equations that determines values of the physical variables in the physical system. For example, the physics-based solver 515 can use the input 505 as initial values of the variables and then perform one or more iterations to modify the initial values based on the set of equations and corresponding conservation laws. The number of iterations is determined adaptively based on a residual drop of the values of the physical variables from the initial values. For example, a residual drop of one order of magnitude is sufficient for the physical variables near the boundaries of the physical system and the object 510 to capture the geometry and flow conditions. The physics-based solver 515 produces an intermediate image 520 of the values of the physical variables.

The intermediate image 520 is provided to a trained DL algorithm 525 that performs inference on the values of the physical variables in the intermediate image 520 to determine an estimated image 530 that indicates estimated values of the physical variables. As discussed herein, the inference process implemented by the DL algorithm 525 does not explicitly account for the constraints imposed by the set of physical equations or the corresponding conservation laws. Thus, the estimated values of the physical variables in the estimated image 530 do not necessarily satisfy either the physical equations or the conservation laws for the physical system. In some embodiments, the inference loss of the trained DL algorithm 525 is less than an error tolerance (for the physical equations or the conservation laws) compared to ground truth data. In that case, the estimated image 530 can be returned as an output tensor that represents the final values of the physical variables. The trained DL algorithm 525 would therefore act as a surrogate of the set of equations and conservation laws that govern the physical system. However, there are several drawbacks to relying exclusively on the results of the trained DL algorithm 525. First, the convergence criteria for the DL algorithm 525 is based on error metrics that lack physical meaning and can be ill-defined. Second, satisfying the conservation laws can be imperative in some situations. Third, ground truth data is typically not available and it may be difficult or impossible to evaluate the accuracy of the results produced by the DL algorithm 525 without ground truth data for comparison.

In the illustrated embodiment, the estimated image 530 is provided to an instance of the physics-based solver 515, which performs one or more additional iterations of the numerical solution to the set of equations to refine the values of the physical variables in the estimated image 530. The physics-based solver 515 applies convergence criteria determined based on changes in the values of the physical variables between iterations and the constraints imposed by the conservation laws. For example, the physics-based solver 515 determines that the numerical solution has converged in response to a residual of the physical variables dropping by 4-5 orders of magnitude. In addition, the physics-based solver 515 requires that the relevant conservation laws be satisfied to within a predetermined tolerance. In response to convergence of the solution, the physics-based solver 515 generates a final image 535 of the final values of the physical variables.

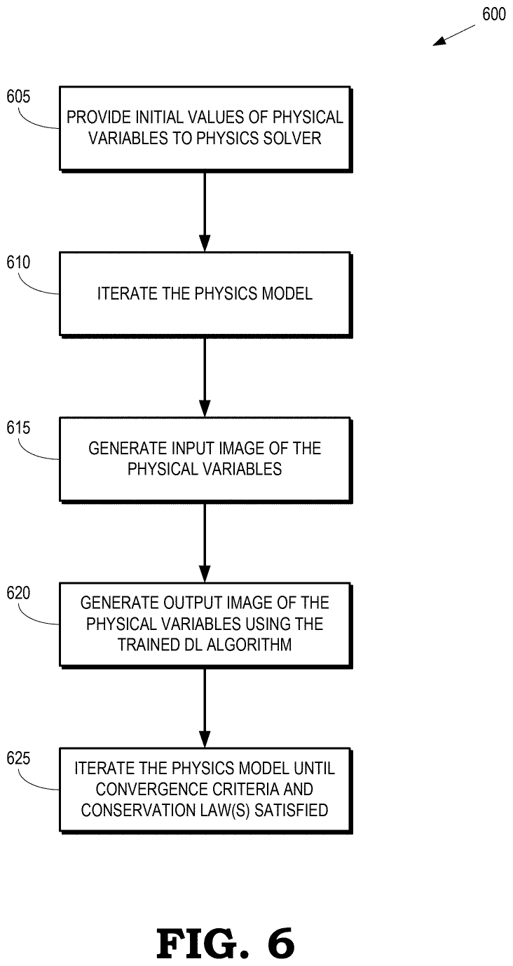

FIG. 6 is a flow diagram of a method 600 of accelerating a physics-based solver using a DL algorithm according to some embodiments. The method 600 is implemented in some embodiments of the processing system 100 shown in FIG. 1 and the processing system 500 shown in FIG. 5.

At block 605, initial values of the physical variables that represent a state of a physical system are provided to a physics-based solver that implements a numerical technique for solving the equations subject to one or more conservation laws. For example, the physics-based solver can generate a numerical solution of discretized versions of the equations and conservation laws for values of the physical variables on a grid or mesh of cells.

At block 610, the physics-based solver performs one or more iterations of the numerical solution based on the physical equations and the conservation laws. The values of the physical variables are updated after each iteration. In some embodiments, the number of iterations of the numerical solution performed by the physics-based solver is determined dynamically based on an amplitude or rate of change of the physical variables, the conservation laws, or a combination or subset thereof.

At block 615, an input image of the physical variables is generated based on the values of the physical variables determined by the physics-based solver. In some embodiments, the input image is used to provide values of the physical variables via different channels, as shown in FIG. 3.

At block 620, the input image generated by the physics-based solver is provided to a DL algorithm that has been trained on data from other simulations. The DL algorithm performs inference on the input image to generate an output image of the physical variables. The output image includes estimated values of the physical variables that do not necessarily satisfy the requirements of the equations that govern the physical system or the relevant conservation laws. The output image of the estimated values is therefore provided to the physics-based solver for a refinement stage.

At block 625, the physics-based solver performs one or more iterations of the physics model beginning with the estimated values of the physical variables inferred by the trained DL algorithm. The physics-based solver continues to perform iterations of the numerical solution of the set of equations until the relevant convergence criteria and conservation laws are satisfied. In response to determining that the convergence criteria and conservation laws are satisfied, the physics-based solver returns a final image of the values of the physical variables present the final state of the physical system.

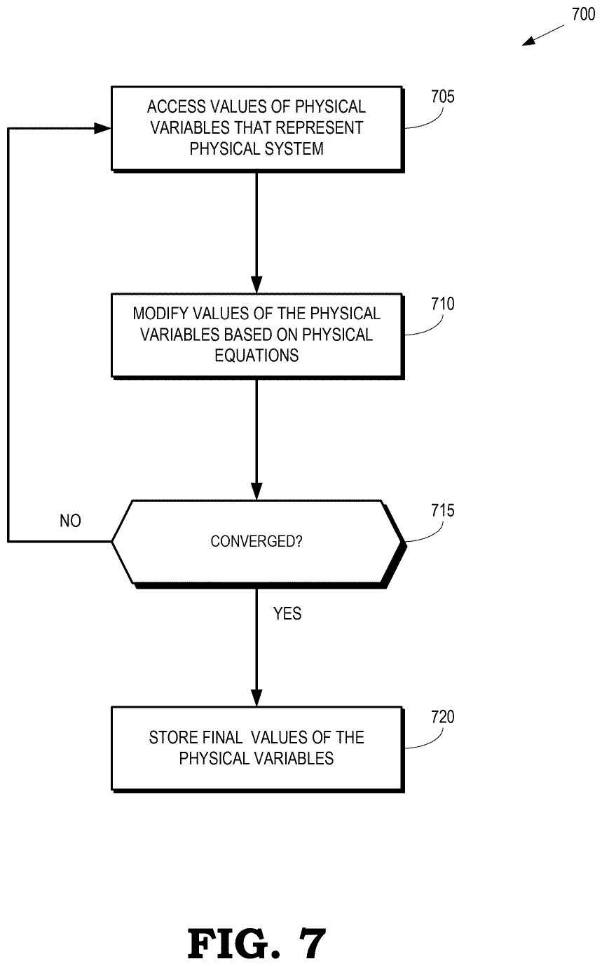

FIG. 7 is a flow diagram of a method 700 of executing a physics-based solver to solve a set of equations that represent a state of a physical system according to some embodiments. The method 700 is implemented in some embodiments of the processing system 100 shown in FIG. 1 and the processing system 500 shown in FIG. 5. The method 700 is also used to implement some embodiments of the block 625 in the method 600 shown in FIG. 6.

At block 705, the physics-based solver accesses values of physical variables that represent a physical system. In some embodiments, the values of the physical variables are initial values or values that are generated by a trained DL algorithm, as discussed herein.

At block 710, the physics-based solver modifies values of the physical variables based on the physical equations that represent the state of the physical system. In some embodiments, the physics-based solver modifies the values by solving discretized forms of the equations on a structured grid with corresponding boundary conditions using numerical finite difference techniques.

At decision block 715, the physics-based solver determines whether the numerical solution has converged. Some embodiments of the physics-based solver determine whether the numerical solution has converged based on changes in the values of the physical variables between iterations and the constraints imposed by the conservation laws. For example, the physics-based solver determines that the numerical solution has converged in response to a residual of the physical variables dropping by 4-5 orders of magnitude. In addition, the physics-based solver requires that the relevant conservation laws be satisfied to within a predetermined tolerance. If the numerical solution has not converged, the method 700 flows back to the block 705. If the numerical solution has converged, the method 700 flows to block 720.

At block 720, the physics-based solver stores the final values of the physical variables. For example, the final values of the physical variables can be stored in a memory such as the memory 105 shown in FIG. 1.

A computer-readable storage medium includes any non-transitory storage medium, or combination of non-transitory storage media, accessible by a computer system during use to provide instructions and/or data to the computer system. Such storage media can include, but is not limited to, optical media (e.g., compact disc (CD), digital versatile disc (DVD), Blu-Ray disc), magnetic media (e.g., floppy disc, magnetic tape, or magnetic hard drive), volatile memory (e.g., random access memory (RAM) or cache), non-volatile memory (e.g., read-only memory (ROM) or Flash memory), or microelectromechanical systems (MEMS)-based storage media. The computer readable storage medium can be embedded in the computing system (e.g., system RAM or ROM), fixedly attached to the computing system (e.g., a magnetic hard drive), removably attached to the computing system (e.g., an optical disc or Universal Serial Bus (USB)-based Flash memory), or coupled to the computer system via a wired or wireless network (e.g., network accessible storage (NAS)).

In some embodiments, certain aspects of the techniques described above are implemented by one or more processors of a processing system executing software. The software includes one or more sets of executable instructions stored or otherwise tangibly embodied on a non-transitory computer readable storage medium. The software can include the instructions and certain data that, when executed by the one or more processors, manipulate the one or more processors to perform one or more aspects of the techniques described above. The non-transitory computer readable storage medium can include, for example, a magnetic or optical disk storage device, solid state storage devices such as Flash memory, a cache, random access memory (RAM) or other non-volatile memory device or devices, and the like. The executable instructions stored on the non-transitory computer readable storage medium can be in source code, assembly language code, object code, or other instruction format that is interpreted or otherwise executable by one or more processors.

Note that not all of the activities or elements described above in the general description are required, that a portion of a specific activity or device may not be required, and that one or more further activities may be performed, or elements included, in addition to those described. Still further, the order in which activities are listed are not necessarily the order in which they are performed. Also, the concepts have been described with reference to specific embodiments. However, one of ordinary skill in the art appreciates that various modifications and changes can be made without departing from the scope of the present disclosure as set forth in the claims below. Accordingly, the specification and figures are to be regarded in an illustrative rather than a restrictive sense, and all such modifications are intended to be included within the scope of the present disclosure.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims. Moreover, the particular embodiments disclosed above are illustrative only, as the disclosed subject matter may be modified and practiced in different but equivalent manners apparent to those skilled in the art having the benefit of the teachings herein. No limitations are intended to the details of construction or design herein shown, other than as described in the claims below. It is therefore evident that the particular embodiments disclosed above may be altered or modified and all such variations are considered within the scope of the disclosed subject matter. Accordingly, the protection sought herein is as set forth in the claims below.

What is claimed is:

1. A computer-implemented method comprising:
estimating first values of physical variables that represent a first state of a first physical system determined by at least one physical equation and subject to at least one conservation law using a deep learning (DL) algorithm that is trained based on second values of the physical variables that represent a second state of a second physical system; and
executing a physics-based model to modify the estimated first values based on the at least one physical equation, wherein the modified first values satisfy the at least one conservation law.

2. The method of claim 1, wherein executing the physics-based model comprises executing iterations of the physics-based model until the modified first values of the physical variables satisfy the at least one conservation law and at least one convergence criterion to a predetermined accuracy or threshold.

3. The method of claim 1, wherein the first values of the physical variables represent a static, time-independent state of the first physical system.

4. The method of claim 1, wherein the first values of the physical variables represent at least one dynamic, time-dependent state of the first physical system.

5. The method of claim 1, wherein the DL algorithm comprises a convolutional neural network (CNN) that implements activation functions to estimate the first values of the physical variables in a grid of cells that represents the first state of the first physical system.

6. The method of claim 5, wherein initial values of the physical variables are provided to the CNN as a set of channels.

7. The method of claim 6, further comprising:
executing the physics-based model to generate the initial values of the physical variables that are provided to the CNN.

8. The method of claim 7, further comprising:
training the CNN using intermediate iterations as a training input and an output of the CNN as a target variable.

9. The method of claim 1, wherein the physics-based model implements computational fluid dynamics (CFD) to solve one or more Navier-Stokes equations that represent the first state of the first physical system.

10. An apparatus comprising:
a memory configured to store program code representative of:
a deep learning (DL) algorithm that is trained based on models of physical variables that represent states of physical systems determined by at least one physical equation and subject to at least one conservation law, and
a physics-based model configured to determine values of the physical variables by solving the at least one physical equation subject to the at least one conservation law; and
at least one processor configured to execute the DL algorithm to estimate values of the physical variables that represent a state of a physical system and to execute the physics-based model to modify the estimated values based on the at least one physical equation, wherein the modified values satisfy the at least one conservation law.

11. The apparatus of claim 10, wherein the at least one processor is configured to execute iterations of the physics-based model until the modified values of the physical variables satisfy the at least one conservation law and at least one convergence criterion to a predetermined accuracy or threshold.

12. The apparatus of claim 10, wherein the values of the physical variables represent a static, time independent state of the first physical system.

13. The apparatus of claim 10, wherein the values of the physical variables represent at least one dynamic, time-dependent state of the first physical system.

14. The apparatus of claim 10, wherein the DL algorithm comprises a deep neural network (DNN) that implements activation functions to estimate the values of the physical variables in a grid of cells that represents the state of the physical system.

15. The apparatus of claim 14, wherein initial values of the physical variables are provided to the DNN as a set of channels.

16. The apparatus of claim 15, wherein the at least one processor is configured to execute the physics-based model to generate the initial values of the physical variables that are provided to the DNN.

17. The apparatus of claim 16, wherein the at least one processor is configured to train the CNN using intermediate iterations as a training input and an output of the DNN as a target variable.

18. The apparatus of claim 10, wherein the physics-based model implements computational fluid dynamics (CFD) to solve one or more Navier-Stokes equations that represent the state of the physical system.

19. A computer-implemented method comprising:
training a deep learning (DL) algorithm based on models of physical variables that represent states of physical systems determined by at least one physical equation and subject to at least one conservation law; and
estimating, using the trained DL algorithm, values of the physical variables that represent a state of a physical system.

20. The method of claim 19, further comprising:
modifying, using a physics-based solver, the estimated values of the physical variables by solving the at least one physical equation subject to the at least one conservation law.
